(19) United States
(12) Patent Application Publication
(10) Pub. No.: US 2020/0028032 A1
(43) Pub. Date: Jan. 23, 2020

(54) LIGHT EMITTING STRUCTURE AND MANUFACTURING METHOD THEREOF

(71) Applicants: LITE-ON OPTO TECHNOLOGY (CHANGZHOU) CO., LTD., Changzhou City (CN); LITE-ON TECHNOLOGY CORPORATION, Taipei City (TW)

(72) Inventors: KAI-CHIEH LIANG, New Taipei City (TW); KUO-MING CHIU, New Taipei City (TW); WEI-TE CHENG, Taipei City (TW)

(21) Appl. No.: 16/413,659

(22) Filed: May 16, 2019

(30) Foreign Application Priority Data
Jul. 20, 2018 (CN) 201810800194.1

(51) Int. Cl. H01L 33/48; H01L 33/58; H01L 33/60

(52) U.S. Cl. CPC H01L 33/486; H01L 33/58; H01L 2933/0033; H01L 2933/0058; H01L 33/60

(57) ABSTRACT

A light emitting structure includes a substrate, a light emitting unit disposed on the substrate, an annular wall, a first bonding layer adhering to the annular wall and the substrate, and a compound body. The light emitting unit is arranged inside of the annular wall. The annular wall, the first bonding layer, and the first surface surroundingly define a gap. The compound body is arranged in a space defined by the annular wall, and includes a reinforcing portion filled in the gap so as to connect the annular wall, the first bonding layer, and the substrate.

### CROSS-REFERENCE TO RELATED PATENT APPLICATION

This application claims the benefit of priority to China Patent Application No. 201810800194.1, filed on Jul. 20, 2018 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light emitting structure and a manufacturing method thereof.

### BACKGROUND OF THE DISCLOSURE

A conventional light emitting structure includes a substrate, a retaining wall adhered to the substrate via a single adhesive layer, a light emitting unit disposed on the substrate and arranged inside of the retaining wall. However, the adhering force of the single adhesive layer is usually insufficient, generating defects in the conventional light emitting structure.

### SUMMARY OF THE DISCLOSURE

In response to the above-referenced technical inadequacies, the present disclosure provides a light emitting structure and a manufacturing method thereof.

The present disclosure provides a light emitting structure, which includes a substrate, a light emitting unit, an annular wall, a first bonding layer, and a compound body. The light emitting unit is disposed on the substrate and is covered by the compound body. The annular wall is fixed on the substrate through the first bonding layer and a reinforcing portion of the compound body.

In one aspect, the present disclosure provides a manufacturing method of a light emitting structure.

Therefore, in the present disclosure, the annular wall and the substrate are connected to each other by the first bonding layer and the reinforcing portion that is connected to the first bonding layer, so that the annular wall can be firmly fixed to the substrate for effectively reducing the probability of occurrence of defects generated in the light emitting structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, in which:

FIG. 1A is a top planar view of a light emitting structure according to a first embodiment of the present disclosure when a light-permeable cover, a second bonding layer, and a compound body are omitted;

FIG. 1B is a cross-sectional view of the light emitting structure according to the first embodiment of the present disclosure;

FIG. 2 is an enlarged view of portion II of FIG. 1B;

FIG. 3 is a cross-sectional view showing a preparing step of a manufacturing method of the light emitting structure according to the first embodiment of the present disclosure;

FIG. 4 is a cross-sectional view showing the preparing step of the manufacturing method of the light emitting structure according to the first embodiment of the present disclosure when a side lens is formed;

FIG. 5 is a cross-sectional view showing a filling step of the manufacturing method of the light emitting structure according to the first embodiment of the present disclosure;

FIG. 6 is a cross-sectional view showing a solidifying step of the manufacturing method of the light emitting structure according to the first embodiment of the present disclosure;

FIG. 7 is a cross-sectional view showing an adhering step of the manufacturing method of the light emitting structure according to the first embodiment of the present disclosure;

FIG. 8 is a cross-sectional view of a light emitting structure according to a second embodiment of the present disclosure;

FIG. 9 is an enlarged view of portion IX of FIG. 8;

FIG. 10 is a cross-sectional view of a light emitting structure according to a third embodiment of the present disclosure; and

FIG. 11 is a cross-sectional view of a light emitting structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

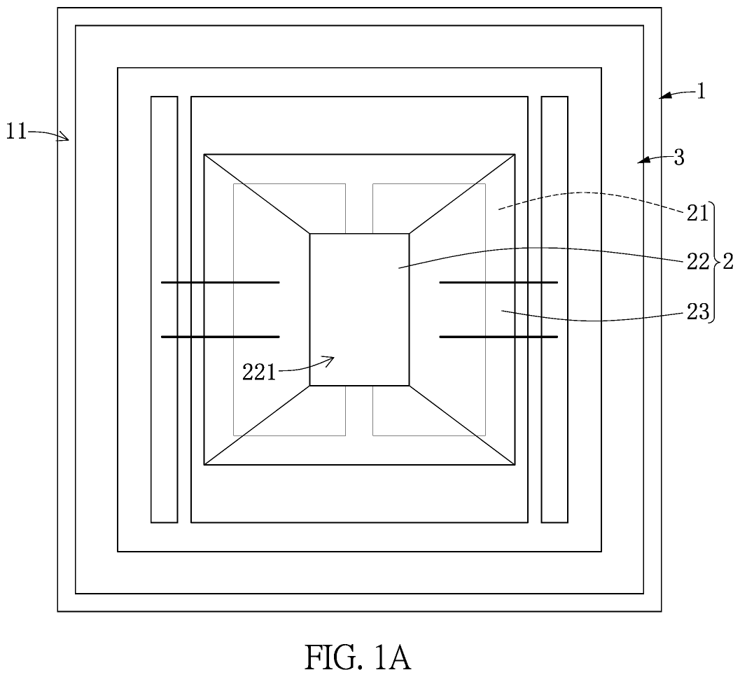

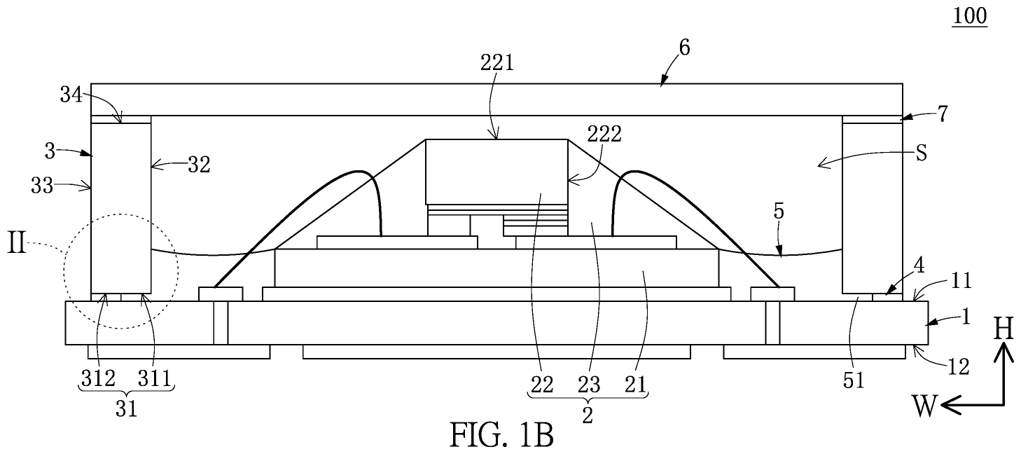

Referring to FIG. 1A to FIG. 7, a first embodiment of the present disclosure provides a light emitting structure 100 and a manufacturing method thereof. The light emitting structure 100 of the present embodiment can be a UV emitting structure or a UV LED package structure, but the present disclosure is not limited thereto. It should be noted that, the following description discloses the light emitting structure 100, and then discloses the manufacturing method of the light emitting structure 100, but the light emitting structure 100 of the present disclosure is not limited to be prepared by the manufacturing method.

The light emitting structure 100 includes a substrate 1, a light emitting unit 2 disposed on the substrate 1, an annular wall 3 arranged around the light emitting unit 2, a first bonding layer 4 and a compound body 5 both connecting the annular wall 3 to the substrate 1, a light-permeable cover 6 disposed above the light emitting unit 2 and the annular wall 3, and a second bonding layer 7 connecting the light-permeable cover 6 to the annular wall 3.

The substrate 1 in the present embodiment is a flat plate, and can be a ceramic printed circuit board or a ceramic substrate with electrical circuit, in which the material of the ceramic substrate includes aluminum oxide or aluminum nitride, but the present disclosure is not limited thereto. The substrate 1 has a first surface 11 (e.g., a top surface of the substrate 1 shown in FIG. 1B) and a second surface 12 (e.g., a bottom surface of the substrate 1 shown in FIG. 1B) opposite to the first surface 11. Moreover, the substrate 1 of the present embodiment defines a height direction H substantially perpendicular to the first surface 11 of the substrate 1 and a width direction W substantially parallel to the first surface 11 of the substrate 1.

The light emitting unit 2 is disposed on the first surface 11 of the substrate 1, and the connection between the light emitting unit 2 and the first surface 11 can be adjusted according to design requirements. In the present embodiment, the light emitting unit 2 includes a carrier 21 disposed on the first surface 11 of the substrate 1, a light emitting chip 22 disposed on the carrier 21, and a side lens 23 disposed on the carrier 21 and surrounding the light emitting chip 22. However, in other embodiments of the present disclosure, the light emitting unit 2 can be provided without the carrier 21, and the light emitting chip 22 is directly disposed and mounted on the substrate 11.

The light emitting chip 22 has a light emitting surface 221 and a surrounding lateral surface 222 that is connected to a periphery edge of the light emitting surface 221. The light emitting chip 22 is fixed on the carrier 21, and the light emitting surface 221 is arranged on one side of the light emitting chip 22 away from the carrier 21 (e.g., a top side of the light emitting chip 22 shown in FIG. 1B). The carrier 21 is electrically connected to the substrate 1 by at least one metal wire, and the light emitting chip 22 is electrically connected to the substrate 1 through the carrier 21. The side lens 23 is formed on the carrier 21, and the surrounding lateral surface 222 of the light emitting chip 22 is entirely covered by the side lens 23. Moreover, the at least one metal wire in the present embodiment is partially embedded in the side lens 23, and the side lens 23 does not cover the light emitting surface 221 of the light emitting chip 22.

Specifically, the light emitting chip 22 can be a UV chip or a UV LED chip, and is preferably configured to emit UV light having a wavelength within a range of 190-420 nm, but the present disclosure is not limited thereto.

In other embodiments of the present disclosure, the light emitting unit 2 can be fixed on the substrate 1 by flip-chip bonding the light emitting chip 22 onto the substrate 1 so as to omit the carrier 21 and the at least one metal wire; or the light emitting unit 2 can be formed without the carrier 21, the side lens 23, and the at least one metal wire.

The material of the annular wall 3 can include metal (e.g., aluminum) or polymer, and a height of the annular wall 3 with respect to the first surface 11 is preferably larger than or equal to a height of the light emitting unit 2 with respect to the first surface 11. A bottom surface 31 of the annular wall 3 is fixed to the first surface 11 of the substrate 1 through the first bonding layer 4, so that an inner periphery surface 32 of the annular wall 3 and the first surface 11 of the substrate 1 can jointly define an accommodating space S, and the light emitting unit 2 is arranged in the accommodating space S.

An outer periphery surface 33 of the annular wall 3 preferably does not protrude from an outer lateral edge of the substrate 1. In other words, the outer periphery surface 33 of the annular wall 3 is flush with the outer lateral edge of the substrate 1, or is arranged at an inner side of the outer lateral edge of the substrate 1 by a distance, but the present disclosure is not limited thereto.

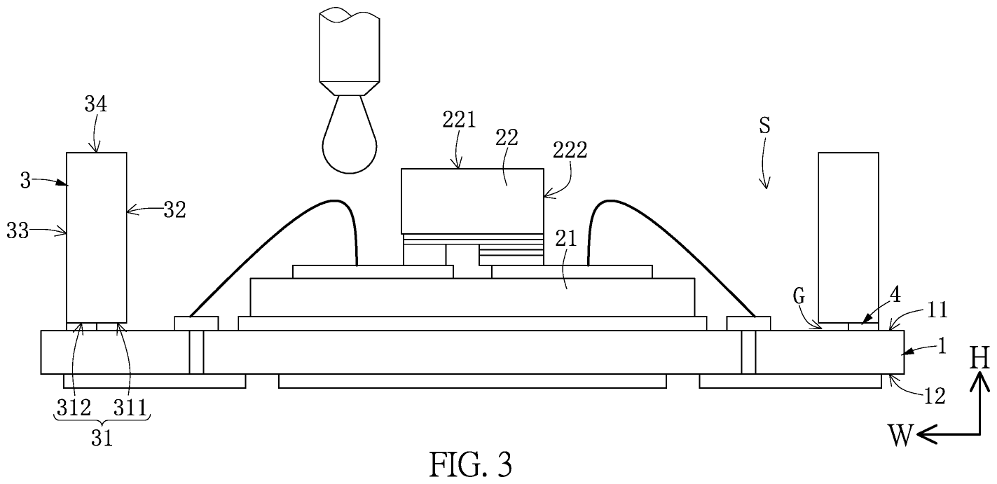

Moreover, the bottom surface 31 of the annular wall 3, the first bonding layer 4 (e.g., an inner edge of the first bonding layer 4 shown in FIG. 3), and the first surface 11 (e.g., a part of the first surface 11 facing the bottom surface 31 shown in FIG. 3) surroundingly define a gap G (as shown in FIG. 3) that is in spatial-communication with the accommodating space S.

Specifically, the bottom surface 31 of the annular wall 3 includes an inner fixing region 311 and an outer fixing region 312 that is arranged outside the inner fixing region 311. In the width direction W, a width W311 of the inner fixing region 311 is 10-70% of a width W31 of the bottom surface 31 of the annular wall 3. Moreover, the width W311 is preferable 15-50% of the width W31. The first bonding layer 4 is in an annular shape, and at least part of the outer fixing region 312 is adhered to the first bonding layer 4. The outer fixing region 312 in the present embodiment is entirely adhered to the first bonding layer 4, but the present disclosure is not limited thereto.

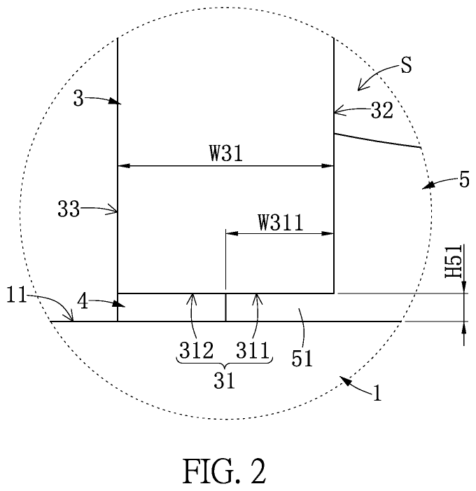

The compound body 5 is arranged in the accommodating space S to cover the carrier 21. That is to say, the carrier 21 is embedded in the compound body 5. The compound body 5 includes a reinforcing portion 51 (as shown in FIG. 2) filled in the gap G so as to connect the bottom surface 31 of the annular wall 3, the first bonding layer 4 (e.g., the inner edge of the first bonding layer 4 shown in FIG. 2), and the first surface 11 (e.g., the part of the first surface 11 facing the bottom surface 31 shown in FIG. 2).

Accordingly, the bottom surface 31 of the annular wall 3 and the first surface 11 of the substrate 1 are connected to each other by the first bonding layer 4 and the reinforcing portion 51 that is connected to the first bonding layer 4, so that the annular wall 3 can be firmly fixed to the substrate 1 for effectively reducing the probability of occurrence of defects generated in the light emitting structure 100.

Specifically, at least 80% of the inner fixing region 311 can be adhered to the reinforcing portion 51, and the inner fixing region 311 in the present embodiment is entirely adhered to the reinforcing portion 51, but the present disclosure is not limited thereto. Moreover, a height H51 of the reinforcing portion 51 with respect to the first surface 11 is within a range of 10-100 μm, and the height H51 is preferably within a range of 20-65 μm. If the height H51 of the reinforcing portion 51 is not in the above range, the annular wall 3 is easily separated from the substrate 1 as receiving an external force.

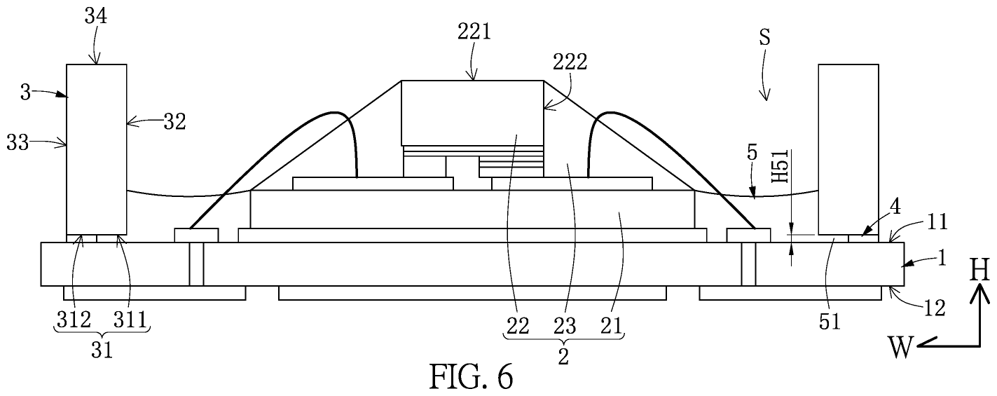

In addition, a top surface of the compound body 5 in the present embodiment is a concave surface, and an edge of the top surface of the compound body 5 is connected to an edge of a top surface of the carrier 21, but the present disclosure is not limited thereto. In other embodiments of the present disclosure, the compound body 5 can be formed by molding so as to have a planar top surface; or the compound body 5 can be formed by twice dispensing (e.g., the top surface of the compound body 5 shown in FIG. 6 is further dispensed with some liquid compound) so as to have a planar top surface.

The light-permeable cover 6 in the present embodiment is a transparent glass that is in a flat plate shape, but the present disclosure is not limited thereto. The light-permeable cover 6 is fixed to a top surface 34 of the annular wall 3 through the second bonding layer 7, so that the accommodating space S can be sealed, but the present disclosure is not limited thereto. For example, in other embodiments of the present disclosure, the second bonding layer 7 can be distributed on four corners of the top surface 34 of the annular wall 3 to adhere the light-permeable cover 6 to the annular wall 3, so that the accommodating space S can be in spatial-communication with an external space. An outer edge of the light-permeable cover 6 preferably does not protrude from the outer periphery surface 33 of the annular wall 3. In other words, the outer edge of the light-permeable cover 6 is flush with the outer periphery surface 33 of the annular wall 3, or is arranged at an inner side of the outer periphery surface 33 of the annular wall 3 by a distance, but the present disclosure is not limited thereto.

The light emitting structure 100 of the present embodiment is disclosed in the above description, and the following description discloses the manufacturing method of the light emitting structure 100, but the light emitting structure 100 of the present embodiment is not limited to be prepared by the manufacturing method. The manufacturing method includes a preparing step, a filling step, a solidifying step, and an adhering step, but the present disclosure is not limited to detail features or order of the steps.

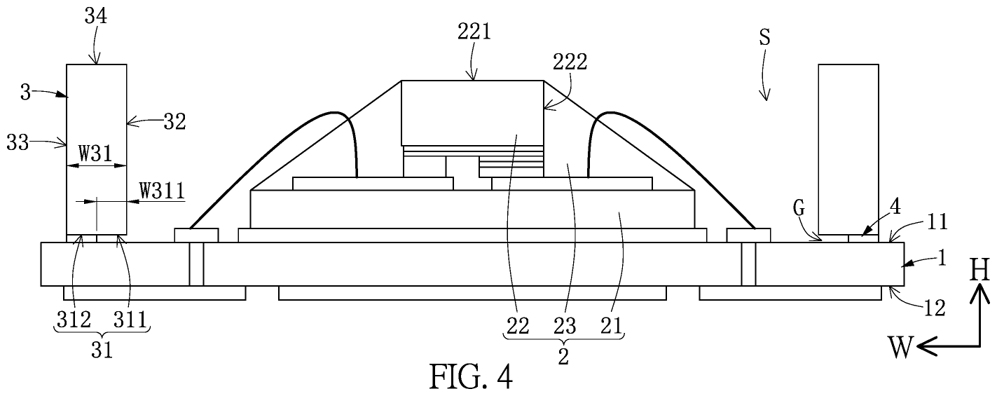

As shown in FIG. 3 and FIG. 4, the preparing step is implemented by disposing the light emitting unit 2 on the first surface 11 of the substrate 1 and fixing the bottom surface 31 of the annular wall 3 to the first surface 11 of the substrate 1 through the first bonding layer 4. The annular wall 3 is arranged around the light emitting unit 2. That is to say, the light emitting unit 2 is arranged in a space surroundingly defined by the annular wall 3. The bottom surface 31 of the annular wall 3, the first bonding layer 4 (e.g., the inner edge of the first bonding layer 4 shown in FIG. 3), and the first surface 11 (e.g., the part of the first surface 11 facing the bottom surface 31 shown in FIG. 3) surroundingly define the gap G.

Specifically, for the light emitting unit 2 of the present embodiment, the carrier 21 carrying the light emitting chip 22 (e.g., a UV chip) is disposed on the first surface 11 of the substrate 1, a compound is dispensed on the carrier 21 and surrounds the light emitting chip 22, a surrounding environment is vacuumed to form a vacuum environment, and the compound is heated to form the side lens 23. Moreover, the surrounding lateral surface 222 of the light emitting chip 22 is entirely covered by the side lens 23, but the present disclosure is not limited thereto.

The bottom surface 31 of the annular wall 3 includes the inner fixing region 311 and the outer fixing region 312 that is arranged outside the inner fixing region 311. At least part (or all) of the outer fixing region 312 is adhered to the first bonding layer 4. In the width direction W, the width W311 of the inner fixing region 311 is 10-70% of the width W31 of the bottom surface 31 of the annular wall 3. Moreover, the width W311 is preferable 15-50% of the width W31.

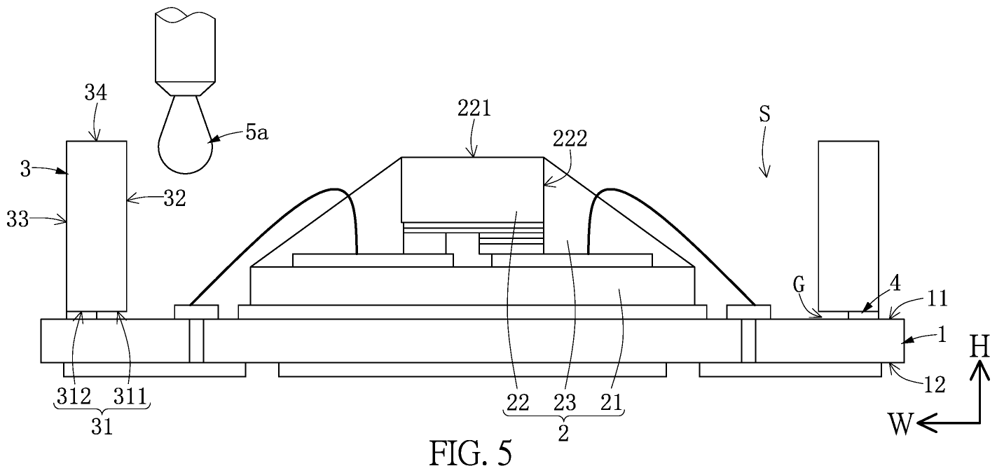

As shown in FIG. 5, the filling step is implemented by filling a liquid compound 5a in the space surroundingly defined by the annular wall 3, and then vacuuming a surrounding environment to gradually form a vacuum environment so as to fill the liquid compound 5a into the gap G (as shown in FIG. 6).

Specifically, the filling step of the present embodiment allows the liquid compound 5a to easily fill into the narrow gap G by using a vacuuming manner, and the vacuuming manner can be adjusted according to design requirements or the shape of the gap G Moreover, gap between the substrate 1 and the carrier 21 can be filled with the liquid compound 5a for achieving no bubble that exists between substrate 1 and the carrier 21.

As show in FIG. 6, the solidifying step is implemented by solidifying the liquid compound 5a to form the compound body 5, so that the carrier 21 of the present embodiment is embedded in the compound body 5. Specifically, a portion of the compound body 5 filled in the gap G is defined as the reinforcing portion 51, and the reinforcing portion 51 connects the bottom surface 31 of the annular wall 3, the first bonding layer 4, and the first surface 11 of the substrate 1. At least 80% (e.g., 100%) of the inner fixing region 311 is adhered to the reinforcing portion 51, and the height H51 of the reinforcing portion 51 with respect to the first surface 11 is within a range of 10-100 μm, but the present disclosure is not limited thereto.

It should be noted that the liquid compound 5a can be solidified to form the compound body 5 in the vacuum environment or in a normal environment.

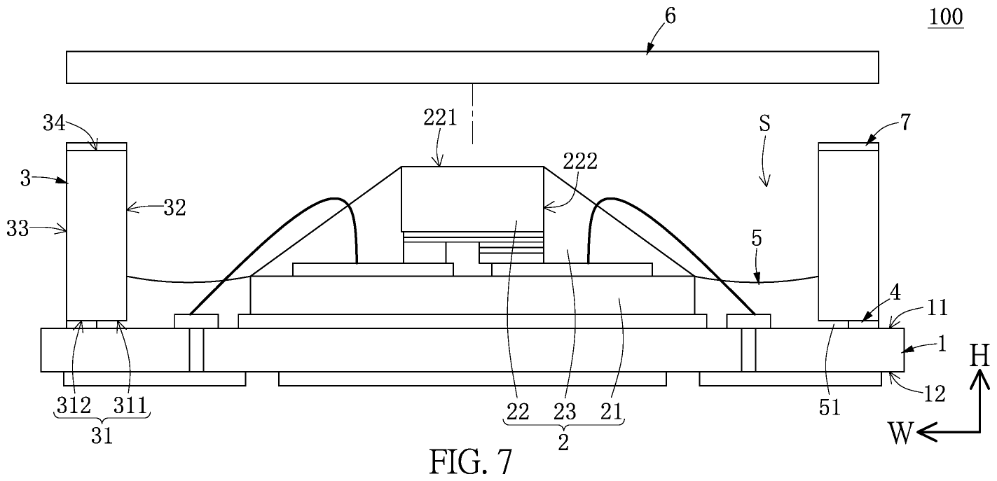

As shown in FIG. 7 and FIG. 1B, the adhering step is implemented by fixing the light-permeable cover 6 to the top surface 34 of the annular wall 3 through the second bonding layer 7, so that the space surroundingly defined by the annular wall 3 can be sealed. Accordingly, the adhering step in the present embodiment can be named as a sealing step. In other embodiments of the present disclosure, the second bonding layer 7 can include a plurality of portions disposed on the top surface 34 of the annular wall 3 (e.g., the four corners of the top surface 34) and spaced apart from each other, so that the space surroundingly defined by the annular wall 3 can be in spatial-communication with an external space, and is regarded as a semi-sealed mode. The light-permeable cover 6 in the present embodiment is a transparent glass that is in a flat plate shape, but the present disclosure is not limited thereto.

In the light emitting structure 100 prepared by the manufacturing method, the probability of the annular wall 3 separated from the substrate 1 can be effectively reduced for increasing the preparing yield of the light emitting structure 100 of the present embodiment.

### Second Embodiment

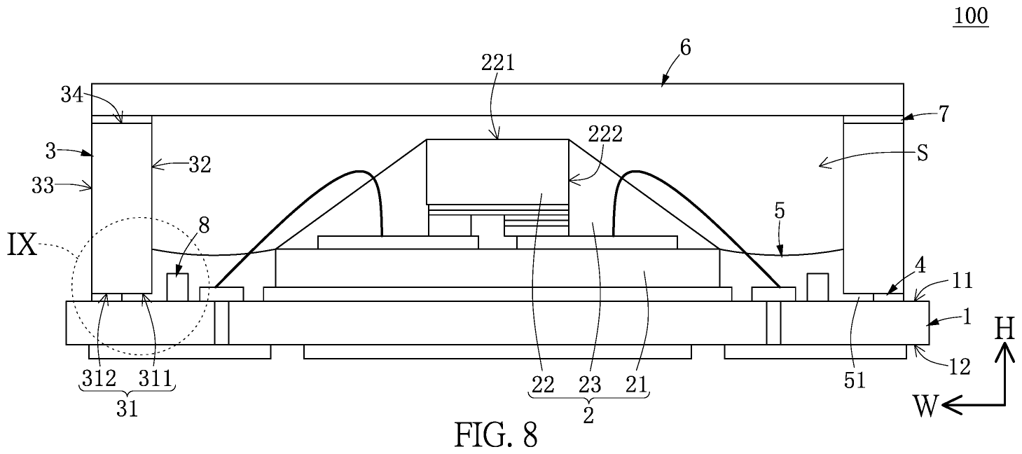

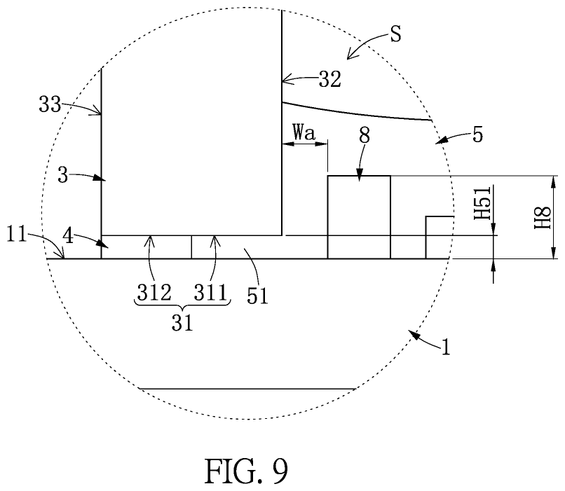

Reference is made to FIG. 8 to FIG. 9, which show a second embodiment of the present disclosure. The present embodiment is similar to the first embodiment, and the difference between the two embodiments is described as follows. The light emitting structure 100 of the present embodiment further includes an annular rib 8 disposed on the first surface 11 of the substrate 1.

Specifically, the annular rib 8 is embedded in the compound body 5 and is arranged adjacent to the reinforcing portion 51, and the annular rib 8 is spaced apart from the reinforcing portion 51 by a runner width Wa. The runner width Wa is larger than or equal to a distance (e.g., the height H51 of the reinforcing portion 51) between the bottom surface 31 of the annular wall 3 and the first surface 11 of the substrate 1, so that the compound body 5 (or the liquid compound 5a) can flow through a channel between the annular rib 8 and the inner periphery surface 32 of the annular wall 3 that has the runner width Wa, which is easier than flow into the gap G.

Specifically, a height H8 of the annular rib 8 with respect to the first surface 11 is more than the height H51 of the reinforcing portion 51 with respect to the first surface 11, so that the annular rib 8 can be configured to effectively shield light (e.g., UV light) emitted from the light emitting chip 22 for preventing the first bonding layer 4 from receiving the light. Accordingly, the service life of the first bonding layer 4 can be increased.

### Third Embodiment

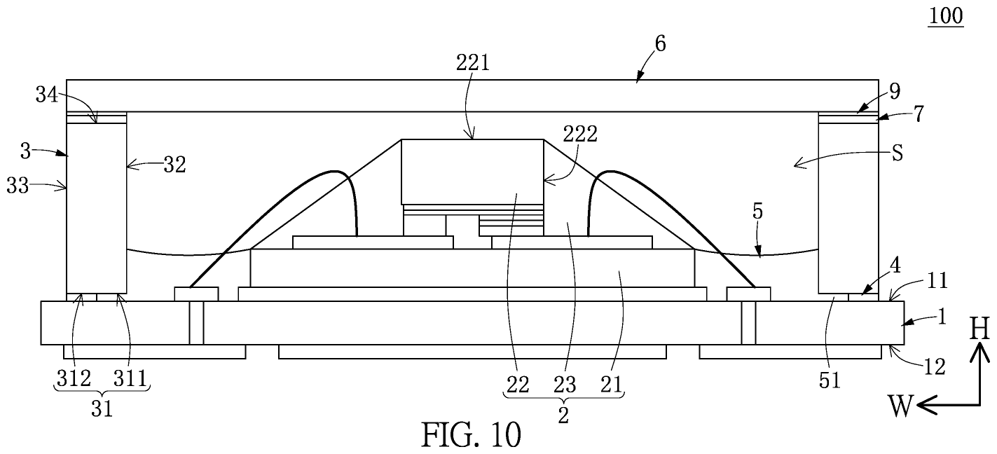

Reference is made to FIG. 10, which shows a third embodiment of the present disclosure. The present embodiment is similar to the first embodiment, and the difference between the two embodiments is described as follows. The light emitting structure 100 of the present embodiment further includes a reflective layer 9.

Specifically, the reflective layer 9 is disposed on a portion of the light-permeable cover 6 (e.g., an outer portion of bottom surface of the light-permeable cover 6 shown in FIG. 10) that is adjacent to the second bonding layer 7. Moreover, the reflective layer 9 is preferably located at a light path that starts from the light emitting chip 22 toward the second bonding layer 7 by traveling through the light-permeable cover 6, but the present disclosure is not limited thereto.

### Fourth Embodiment

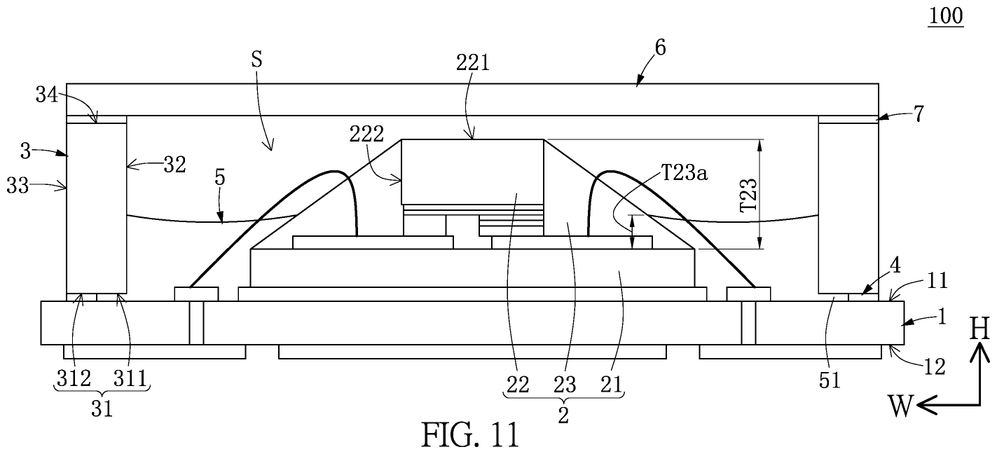

Reference is made to FIG. 11, which shows a fourth embodiment of the present disclosure. The present embodiment is similar to the first embodiment, and the difference between the two embodiments is described as follows. A part of the side lens 23 of the light emitting structure 100 in the present embodiment is covered by the compound body 5.

Specifically, in the height direction H, the part of the side lens 23 covered by the compound body 5 has a thickness T23a that is less than or equal to 50% of a thickness T23 of the side lens 23, thereby preventing the compound body 5 from affecting the lighting performance of the side lens 23.

In conclusion, in the present disclosure, the bottom surface of the annular wall and the first surface of the substrate are connected to each other by the first bonding layer and the reinforcing portion that is connected to the first bonding layer, so that the annular wall can be firmly fixed to the substrate for effectively reducing the probability of occurrence of defects generated in the light emitting structure.

Moreover, the connection between the annular wall and the substrate of the light emitting structure can be further improved by the reinforcing portion. For example, the width of the inner fixing region is 10-70% (e.g., 15-50%) of the width of the bottom surface of the annular wall, at least 80% of the inner fixing region is adhered to the reinforcing portion, and the height of the reinforcing portion with respect to the first surface of the substrate is within a range of 10-100 μm.

In addition, the light emitting structure of the present disclosure can be provided with the annular rib disposed on the first surface of the substrate, so that the annular rib can be configured to effectively shield light (e.g., UV light) emitted from the light emitting chip for preventing the first bonding layer from receiving the light. Accordingly, the service life of the first bonding layer can be increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light emitting structure, comprising:
a substrate;
a light emitting unit disposed on the substrate; and
an annular wall, a first bonding layer, and a compound body, wherein the annular wall is fixed on the substrate through the first bonding layer and the compound body, and the compound body includes a reinforcing portion filled in a gap defined by the annular wall, the first bonding layer, and the substrate.

2. The light emitting structure according to claim 1, wherein the light emitting unit includes:
a carrier disposed on the substrate and embedded in the compound body;
a light emitting chip disposed on the carrier and having a light emitting surface and a surrounding lateral surface that is connected to the light emitting surface; and
a side lens disposed on the carrier, wherein the surrounding lateral surface of the light emitting chip is covered by the side lens.

3. The light emitting structure according to claim 2, wherein a part of the side lens is covered by the compound body, and the substrate defines a height direction perpendicular to the substrate, and wherein in the height direction, the part of the side lens covered by the compound body has a thickness that is less than or equal to 50% of a thickness of the side lens.

4. The light emitting structure according to claim 1, wherein a bottom surface of the annular wall includes an inner fixing region and an outer fixing region that is arranged outside the inner fixing region, and the substrate defines a width direction parallel to the substrate, wherein in the width direction, a width of the inner fixing region is 10-70% of a width of the bottom surface of the annular wall, and wherein at least 80% of the inner fixing region is adhered to the reinforcing portion, and at least part of the outer fixing region is adhered to the first bonding layer.

5. The light emitting structure according to claim 4, wherein in the width direction, the width of the inner fixing region is 15-50% of the width of the bottom surface of the annular wall.

6. The light emitting structure according to claim 1, wherein the substrate defines a height direction perpendicular to the substrate, and wherein in the height direction, a height of the reinforcing portion with respect to the substrate is within a range of 10-100 μm.

7. The light emitting structure according to claim 1, further comprising an annular rib disposed on the substrate and embedded in the compound body, wherein the annular rib is arranged adjacent to the reinforcing portion, and the annular rib is spaced apart from the reinforcing portion by a runner width.

8. The light emitting structure according to claim 7, wherein the runner width is larger than or equal to a distance between a bottom surface of the annular wall and the substrate.

9. The light emitting structure according to claim 7, wherein the substrate defines a height direction perpendicular to the substrate, and wherein in the height direction, a height of the annular rib with respect to the substrate is more than a height of the reinforcing portion with respect to the substrate.

10. The light emitting structure according to claim 1, further comprising a light-permeable cover and a second bonding layer, wherein the light-permeable cover is fixed to a top surface of the annular wall through the second bonding layer.

11. The light emitting structure according to claim 10, further comprising a reflective layer disposed on a portion of the light-permeable cover that is adjacent to the second bonding layer, wherein the reflective layer is located at a light path that starts from the light emitting unit toward the second bonding layer by traveling through the light-permeable cover.

12. A manufacturing method of a light emitting structure, comprising:
implementing a preparing step by disposing a light emitting unit on a substrate and fixing an annular wall to the substrate through a first bonding layer, wherein the annular wall is arranged around the light emitting unit, and the annular wall, the first bonding layer, and the substrate surroundingly define a gap;
implementing a filling step by filling a liquid compound in a space surroundingly defined by the annular wall, and then vacuuming a surrounding environment to gradually form a vacuum environment so as to fill the liquid compound into the gap; and
implementing a solidifying step by solidifying the liquid compound to form a compound body, wherein a portion of the compound body filled in the gap is defined as a reinforcing portion, and the reinforcing portion connects the annular wall, the first bonding layer, and the substrate.

13. The manufacturing method according to claim 12, wherein in the preparing step, a carrier carrying a light emitting chip is disposed on the substrate, a compound is dispensed on the carrier and surrounds the light emitting chip, a surrounding environment is vacuumed to form a vacuum environment, and the compound is heated to form a side lens, wherein a surrounding lateral surface of the light emitting chip is covered by the side lens, and wherein in the solidifying step, the carrier is embedded in the compound body.

14. The manufacturing method according to claim 13, wherein a part of the side lens is covered by the compound body, and the substrate defines a height direction perpendicular to the substrate, and wherein in the height direction, the part of the side lens covered by the compound body has a thickness that is less than or equal to 50% of a thickness of the side lens.

15. The manufacturing method according to claim 12, wherein a bottom surface of the annular wall includes an inner fixing region and an outer fixing region that is arranged outside the inner fixing region, and the substrate defines a width direction parallel to the substrate, wherein in the width direction, a width of the inner fixing region is 10-70% of a width of the bottom surface of the annular wall, and wherein at least 80% of the inner fixing region is adhered to the reinforcing portion, and at least part of the outer fixing region is adhered to the first bonding layer.

16. The manufacturing method according to claim 15, wherein in the width direction, the width of the inner fixing region is 15-50% of the width of the bottom surface of the annular wall.

17. The manufacturing method according to claim 12, wherein the substrate defines a height direction perpendicular to the substrate, and wherein in the height direction, a height of the reinforcing portion with respect to the substrate is within a range of 10-100 μm.

18. The manufacturing method according to claim 12, further fixing a light-permeable cover to a top surface of the annular wall through a second bonding layer.
